(19) United States
(12) Patent Application Publication
(10) Pub. No.: US 2005/0037290 A1
(43) Pub. Date: Feb. 17, 2005

(54) Method for manufacturing light guide plate stamper

(76) Inventor: Ga-Lane Chen, Fremont, CA (US)

Correspondence Address: WEI TE CHUNG;FOXCONN INTERNATIONAL, INC., 1650 MEMOREX DRIVE, SANTA CLARA, CA, 95050, US

(21) Appl. No.: 10/919,938

(22) Filed: Aug. 16, 2004

(30) Foreign Application Priority Data
Aug. 15, 2003 (TW) 92122473

(51) Int. Cl. G03F 7/00

(52) U.S. Cl. 430/320; 430/324

(57) ABSTRACT

A preferred method for manufacturing a light guide plate stamper (6) includes: providing a substrate (1); forming a photo-resist film (2) on the substrate; exposing and developing the photo-resist film to form hardened portions (21); depositing a metal film (5) on the substrate and the hardened portions; plating a metal layer (4) on the metal film by means of electroless deposition; and stripping off the photo-resist film and the substrate.

### BACKGROUND OF THE INVENTION

1. Field of the Invention

The invention generally relates to a method for manufacturing a stamper, and particularly relates to a method for manufacturing a stamper used for manufacturing a light guide plate (LGP) of a backlight module.

2. Prior Art

In recent years, implementation of word processors in compact personal computers has boomed, and portable personal computers known as laptops and notebooks are now in widespread use. In such portable personal computers, a liquid crystal display (LCD) device is commonly used as the display unit.

Conventionally, a backlight module is disposed at a rear side of an LCD screen for lighting the entire LCD screen. To achieve a display with high clarity and resolution, the backlight module providing illumination for the LCD device is required to emit light with high luminance and uniformity. The LGP of the backlight module is key to providing the needed luminance and uniformity. More particularly, the optical performance of micro patterns formed on a bottom surface of the LGP is the most important factor influencing the luminance and uniformity characteristics of the LGP.

Methods for manufacturing an LGP with micro patterns include printing techniques and molding techniques. The method using the printing techniques mainly includes the steps of transcribing predefined micro patterns to a prepared stamper substrate, and manufacturing an LGP with the micro patterns on its bottom surface by utilizing an injection molding or an extrusion molding method. Generally, the molding techniques are considered to be superior to the printing techniques, because the quality of the micro patterns manufactured by molding techniques is better than that of printing techniques.

An LGP with precise micro patterns can be manufactured by using a stamper configured with precise “reverse” micro patterns. Thus, the design and manufacturing of LGP stampers has grown rapidly in recent years.

Taiwan Patent No. 503,170 issued on Sep. 21, 2002 discloses a method for producing an injection molded mold for use in the molding technique. The method comprises: producing a patterned soft photo-mask from a soft film; using photolithography to reproduce the patterned soft photo-mask into a non-conductive female mold; coating a silver film on the non-conductive female mold; electroplating the non-conductive female mold to form a mold core, in which the conductive female mold can be electroplated directly; stripping off the silver film and the non-conductive female mold from the mold core; and putting the mold core into an electrolyte solution to remove any residual silver film.

However, the above-described method for producing the injection molded mold has certain problems. That is, a precision of reverse micro patterns on the mold is generally not satisfactory, because the reverse micro patterns are easily damaged when the silver film is stripped off or when the residual silver film is removed. In addition, said method is somewhat complicated, result in much manufacturing time being spent and correspondingly high costs.

### SUMMARY OF THE INVENTION

An object of the present invention is to provide a relatively easy, low-cost method for manufacturing an LGP stamper that has highly precise micro patterns form thereon.

According to one aspect of the present invention, a preferred method for manufacturing a stamper in accordance with the present invention comprises: providing a substrate; forming a photo-resist film on the substrate; exposing and developing the photo-resist film to form micro patterns; depositing a metal film on the substrate and the micro patterns; plating a metal layer on the metal film by means of electroless deposition; and stripping off the photo-resist film and the substrate.

Other objects, advantages, and novel features of the present invention will become more apparent from the following detailed description when taken in conjunction with the accompanying drawings, in which:

### BRIEF DESCRIPTION OF THE DRAWINGS

FIG. 1 is a flow chart of a preferred method for manufacturing a stamper according to the present invention;

FIGS. 2 to 8 are schematic, cross-sectional views of sequential stages in manufacturing the stamper according to FIG. 1;

FIG. 9 is a flow chart of an alternative method for manufacturing a stamper according to the present invention;

FIGS. 10 to 15 are schematic, cross-sectional views of sequential stages in manufacturing the stamper according to FIG. 9.

### DESCRIPTION OF THE PREFERRED EMBODIMENTS

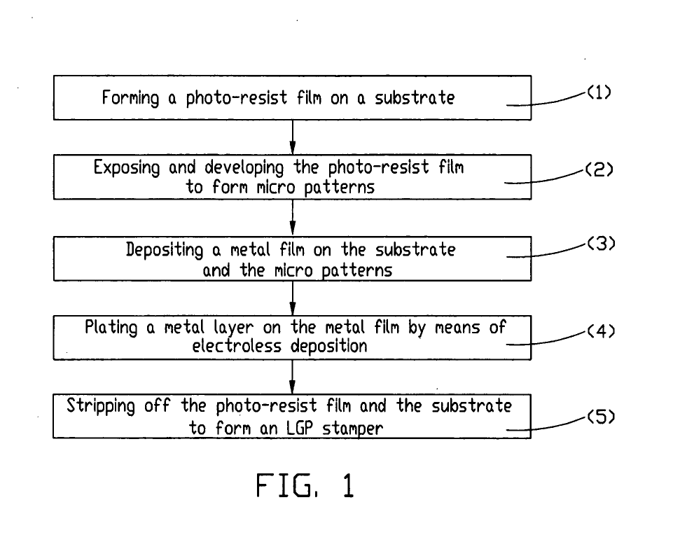

The preferred embodiment of the method for manufacturing an LGP stamper having highly precise micro patterns according to the present invention will be described with reference to the flowchart of FIG. 1.

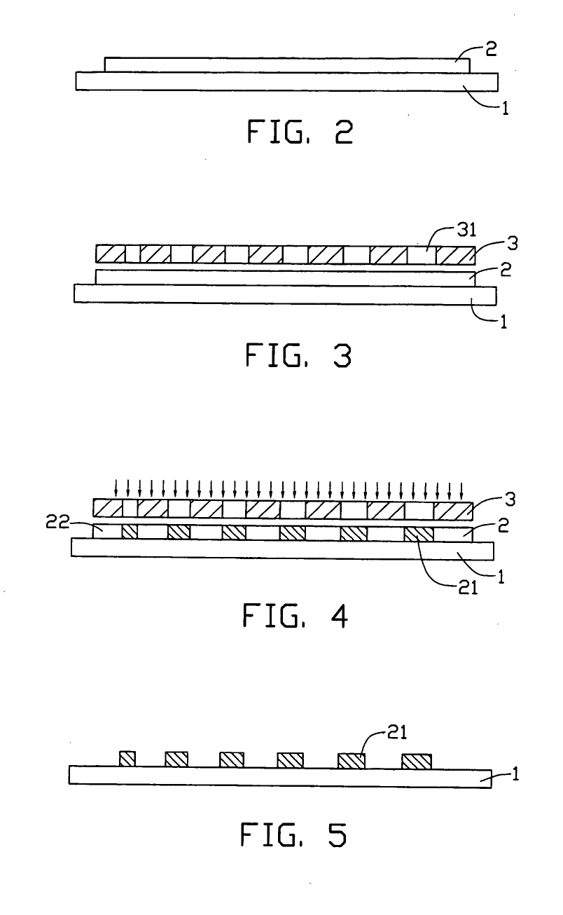

(1) Providing a glass substrate 1, and forming a photo-resist film 2 on the substrate 1 (see FIG. 2). First, the substrate 1 with a smooth surface and a thickness of 2 to 10 millimeters is provided. An adhesion promoting agent of the silane series is then applied on the substrate 1. Second, the substrate 1 is placed on a coating machine (not shown). The photo-resist film 2 is coated on the substrate 1 to a thickness of about 20 microns. Third, the photo-resist film 2 is baked at 140° C. for two hours.

The coating process may be a spin coating process, a roll coating process, or a like process. A liquid or film-like positive or negative photo-resist material can be used. The substrate 1 may alternatively be substituted with a silicon wafer.

(2) Exposing and developing the photo-resist film 2 utilizing a soft photo-mask 3 with patterns 31 to form micro patterns, i.e. hardened portions 21 (see FIGS. 2 to 5). First, the photo-mask 3 with patterns 31 is disposed above the photo-resist film 2. Second, the photo-resist film 2 is illuminated through the photo-mask 3 with ultraviolet rays to form the hardened portions 21 and soluble portions 22. Then the photo-resist film 2 is developed so that the soluble portions 22 are removed and the hardened portions 21 are left on the substrate 1. A distribution of the hardened portions 21 forms patterns similar to the patterns 31 of the photo-mask 3. Thus, a female stamper comprising the substrate 1 and the hardened portions 21 having predetermined patterns similar to the patterns 31 is formed. The exposing step may utilize electron beams, X-rays, a laser beam, or the like.

Further, the developed photo-resist film 2 can be heated and melted, so as to change the shapes of the hardened portions 21 into humped ridges.

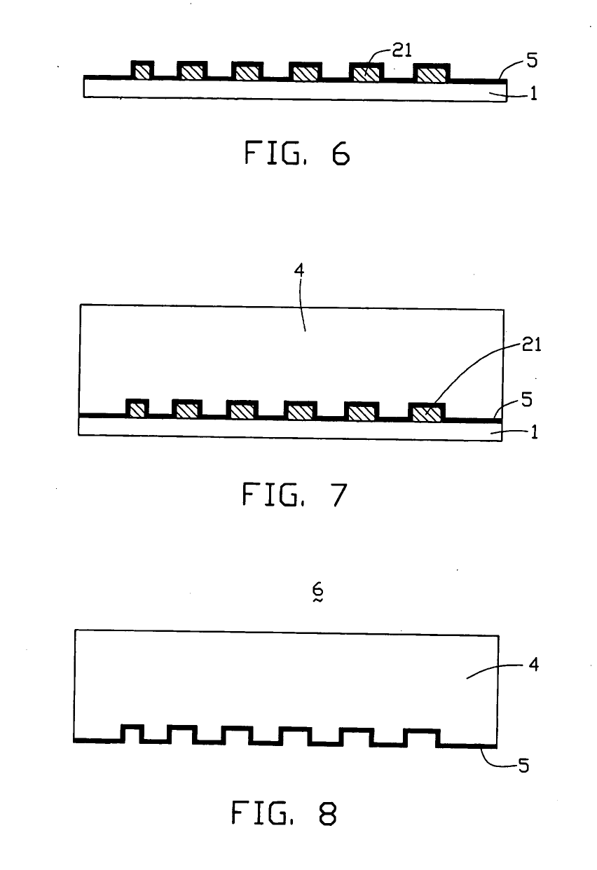

(3) Depositing a metal film 5 on the substrate 1 and the hardened portions 21 to form a stamper core (see FIG. 6). First, the substrate 1 is put in a cavity of a sputtering machine (not shown). Second, the substrate 1 is heated up to 150° C. in air pressure of 0.05 torr. Third, the cavity of the sputtering machine is filled with reactive plasma. Fourth, the metal film 5 is deposited on the patterns 21 and exposed surfaces of the substrate 1 to a thickness of 20˜50 nanometers. Thus, the stamper core is formed. Alternatively, the metal film 5 may be formed by means of evaporation. The metal film 5 may be a nickel film.

(4) Plating a nickel deposition layer 4 on the metal film 5 by means of electroless deposition to form the LGP stamper 6 (see FIGS. 7 and 8). First, the substrate 1 with the metal film 5 is immersed into an electrolyte solution. Second, the electrolyte solution is churned by a magnetic stirrer under a temperature of 88±1° C. Nickel separates from the solution and deposits on the metal film 5. This electroless deposition process is maintained for a suitable time so that the nickel deposition layer 4 attains a thickness of 0.3˜9 millimeters.

There are various ways of performing the process of forming the LGP stamper 6 by means of electroless deposition. In one embodiment, if the metal film 5 is a nickel film, the electrolyte solution mainly comprises NiSO₄.6H₂O, sodium succinate and NaH₂PO₂.H₂O, whose contents are 20 grams/liter, 16 grams/liter and 27 grams/liter respectively. A pH of the solution is set at 4.8.

(5) Stripping off and removing the residual patterns 21 and substrate 1 to form the LGP stamper 6 having the metal film 5 and the nickel deposition layer 4.

It will be appreciated that, unlike the above-described prior art method, the method for manufacturing the LGP stamper 6 in accordance with the present invention does not require a step of separating a silver film from the stamper 6. Thus, there is no risk of the patterns on the LGP stamper 6 sustaining serious damage. The precise micro patterns on the LGP stamper 6 remain intact. In addition, the method for manufacturing the LGP stamper 6 is simple compared to the prior art.

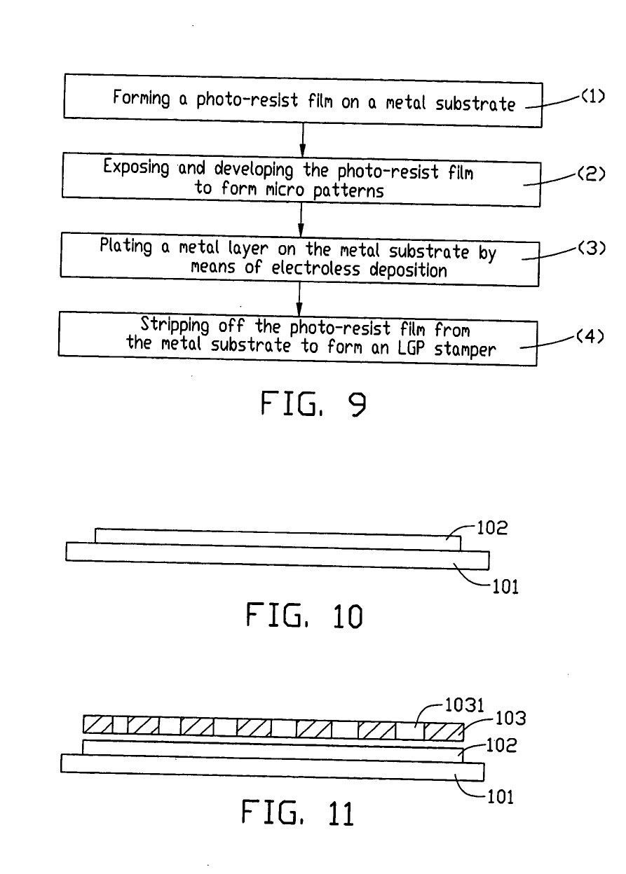

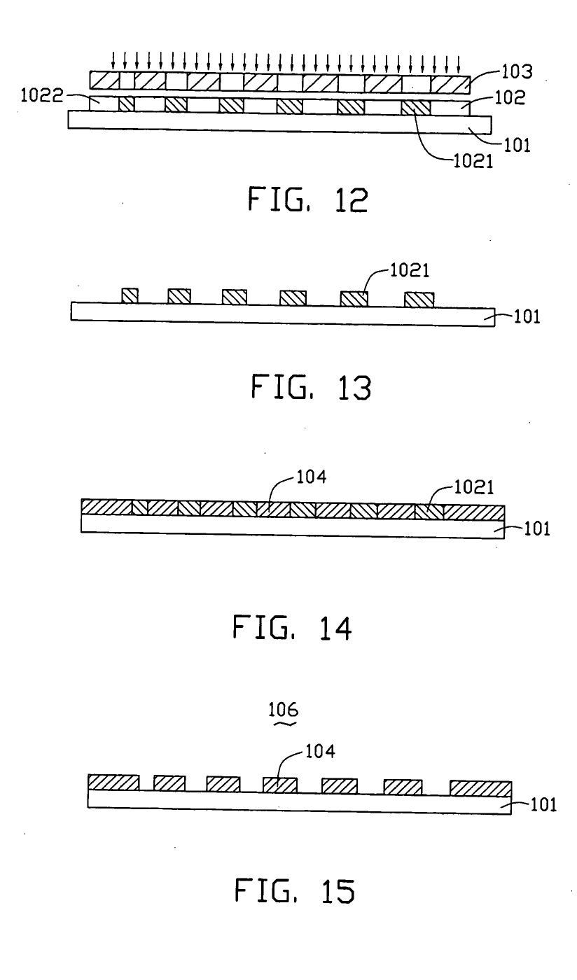

FIGS. 10 to 15 show stages in an alternative embodiment of the method for manufacturing an LGP stamper having highly precise micro patterns according to the present invention, which is described below with reference to the flowchart of FIG. 9:

(1) Providing a substrate 101 made of tooled steel, tungsten carbon or a silicon wafer, and forming a photo-resist film 102 on the substrate 101 (see FIG. 10).

(2) Exposing and developing the photo-resist film 102 utilizing a soft photo-mask 103 with patterns 1031 to form micro patterns, i.e. hardened portions 1021 (see FIGS. 11 to 13). First, the photo-mask 103 with patterns 1031 is provided and disposed above the photo-resist film 102. Second, the photo-resist film 102 is illuminated through the photo-mask 103 using ultraviolet rays to form the hardened portions 1021 and soluble portions 1022 on the substrate 101. Third, the photo-resist film 102 is developed so that the soluble portions 1022 are removed and the hardened portions 1021 are left on the substrate 101. A distribution of the hardened portions 1021 forms patterns similar to the patterns 1031 of the photo-mask 103. Thus, a female stamper comprising the substrate 101 and the hardened portions 1021 with predetermined patterns similar to the patterns 1031 is formed. The exposing step may utilize electron beams, X-rays, a laser beam, or the like.

Further, the developed photo-resist film 102 can be heated and melted, so as to change the shapes of the hardened portions 1021 into humped ridges.

(3) Plating a nickel deposition layer 104 on the substrate 101 by means of electroless deposition to form the LGP stamper 106 (see FIGS. 14 and 15). First, the substrate 101 with the hardened portions 1021 is immersed into an electrolyte solution. Second, the electrolyte solution is churned by a magnetic stirrer under a temperature of 88±1° C. Nickel separates from the electrolyte solution and deposits on uncovered surfaces of the substrate 101. This electroless deposition process is maintained for a suitable time so that the nickel deposition layer 104 attains a thickness that is the same as a thickness of the patterns 1021.

There are various ways of performing the process of forming the LGP stamper 106 by means of electroless deposition. In one embodiment, the electrolyte solution mainly comprises NiSO₄.6H₂O, sodium succinate and NaH₂PO₂.H₂O, whose contents are 20 grams/liter, 16 grams/liter and 27 grams/liter respectively. A pH of the solution is set at 4.8.

(4) Stripping off and removing the residual patterns 1021 from the substrate 101 to form the LGP stamper 106 having the substrate 101 and the nickel deposition layer 104.

It is to be understood that the invention may be embodied in other forms without departing from the spirit thereof. Thus, the present examples and embodiments are to be considered in all respects as illustrative and not restrictive, and the invention is not to be limited to the details given herein.

1. A method for manufacturing a stamper for an LGP (light guide plate), comprising:
providing a substrate;
forming a photo-resist film on the substrate;
exposing and developing the photo-resist film to form micro patterns;
depositing a metal film on the substrate and the micro patterns;
plating a metal layer on the metal film by means of electroless deposition; and
stripping off the photo-resist film and the substrate.

2. The method for manufacturing a stamper for an LGP as claimed in claim 1, wherein the metal layer is a nickel film, and an electrolyte solution used in the electroless deposition comprises NiSO₄.6H₂O, sodium succinate and NaH₂PO₂.H₂O.

3. The method for manufacturing a stamper for an LGP as claimed in claim 2, wherein contents of said NiSO₄.6H₂O, sodium succinate and NaH₂PO₂.H₂O of the electrolyte solution are approximately 20 grams/liter, 16 grams/liter and 27 grams/liter respectively.

4. The method for manufacturing a stamper for an LGP as claimed in claim 1, wherein the substrate is glass or a silicon wafer.

5. The method for manufacturing a stamper for an LGP as claimed in claim 1, wherein the depositing of the metal film on the photo-resist film is performed by way of evaporation or sputtering.

6. The method for manufacturing a stamper for an LGP as claimed in claim 5, wherein a thickness of the metal film is in the range from 20˜50 nanometers.

7. The method for manufacturing a stamper for an LGP as claimed in claim 1, wherein a thickness of the metal layer plated by electroless deposition is in the range from 0.3˜9 millimeters.

8. The method for manufacturing a stamper for an LGP as claimed in claim 1, wherein said metal film and said metal layer are made from a same metal.

9. A method for manufacturing a stamper for an LGP (light guide plate), comprising:
providing a metal substrate;
forming a photo-resist film on the metal substrate;
exposing and developing the photo-resist film to form micro patterns;
plating a metal layer on the metal substrate by means of electroless deposition; and
stripping off the photo-resist film from the metal substrate.

10. The method for manufacturing a stamper for an LGP as claimed in claim 9, wherein the metal substrate is made from tooled steel or tungsten carbon.

11. The method for manufacturing a stamper for an LGP as claimed in claim 9, wherein the metal layer is a nickel film, and an electrolyte solution used in the electroless deposition comprises NiSO₄.6H₂O, sodium succinate and NaH₂PO₂.H₂O.

12. The method for manufacturing a stamper for an LGP as claimed in claim 9, wherein contents of said NiSO₄.6H₂O, sodium succinate and NaH₂PO₂.H₂O of the electrolyte solution are approximately 20 grams/liter, 16 grams/liter and 27 grams/liter respectively.

13. The method for manufacturing a stamper for an LGP as claimed in claim 9, wherein the metal substrate is instead a silicon wafer.

14. A method for manufacturing a stamper for an LGP (light guide plate), comprising:
providing a metal substrate;
forming a photo-resist film on the metal substrate;
exposing and developing the photo-resist film to form hardened portions with micro patterns thereon; and
stripping off the photo-resist film from the metal substrate; wherein
said micro patterns are converted to humped ridges of the metal substrate.

15. The method for manufacturing a stamper for an LGP as claimed in claim 14, further including a step of: plating a metal layer on the metal substrate by means of electroless deposition wherein said metal layer is arranged alternate with regard to the harden portions in a same thickness thereof.
